(19) United States
(12) Patent Application Publication
(10) Pub. No.: US 2013/0344657 A1
(43) Pub. Date: Dec. 26, 2013

(54) PACKAGE ASSEMBLY USING A CARRIER-FREE TECHNIQUE

(71) Applicant: NXP B. V., Eindhoven (NL)

(72) Inventor: Chi-Feng Wu, Kaohsiung (TW)

(73) Assignee: NXP B. V., Eindhoven (NL)

(21) Appl. No.: 13/769,451

(22) Filed: Feb. 18, 2013

Related U.S. Application Data
(60) Provisional application No. 61/664,338, filed on Jun. 26, 2012.

(51) Int. Cl. H01L 21/56; H01L 21/67

(52) U.S. Cl. CPC H01L 21/56; H01L 21/67242
USPC 438/113; 228/102

(57) ABSTRACT

In an example embodiment, there is method for assembling semiconductor devices, the method comprises providing a temporary carrier having a plurality device die locations and a boundary edge. Surrounding the device die locations, electrical connection pads are applied. Device die in the plurality of device die locations are mounted; the device die have pad landings electrically coupled to active components with the device die. The pad landings of the device die are wire bonded to corresponding electrical connection pads. With the molding compound flowing to the boundary edge of the temporary carrier, the device die are encapsulated. In a particular example embodiment, the electrical connection pads may be ball bonds.

### FIELD

The embodiments of the present disclosure relate to semiconductor device packaging and, more particularly, to packaging semiconductor devices using a temporary reusable carrier.

### BACKGROUND

The electronics industry continues to rely upon advances in semiconductor technology to realize higher-function devices in more compact areas. For many applications realizing higher-functioning devices requires integrating a large number of electronic devices into a single silicon wafer. As the number of electronic devices per given area of the silicon wafer increases, the manufacturing process becomes more difficult.

Many varieties of semiconductor devices have been manufactured having various applications in numerous disciplines. Such silicon-based semiconductor devices often include metal-oxide-semiconductor field-effect transistors (MOSFET), such as p-channel MOS (PMOS), n-channel MOS (NMOS) and complementary MOS (CMOS) transistors, bipolar transistors, BiCMOS transistors. Such MOSFET devices include an insulating material between a conductive gate and silicon-like substrate; therefore, these devices are generally referred to as IGFETs (insulated-gate FET).

Each of these semiconductor devices generally includes a semiconductor substrate on which a number of active devices are formed. The particular structure of a given active device can vary between device types. For example, in MOS transistors, an active device generally includes source and drain regions and a gate electrode that modulates current between the source and drain regions.

Furthermore, such devices may be digital or analog devices produced in a number of wafer fabrication processes, for example, CMOS, BiCMOS, Bipolar, etc. The substrates may be silicon, gallium arsenide (GaAs) or other substrate suitable for building microelectronic circuits thereon.

The packaging of semiconductor devices continues to pose a challenge in the reducing of cost and increasing of performance. Furthermore, there is a push towards re-use and recycling of materials in manufacturing processes so as to reduce the waste stream into the environment.

There is exists a need for reducing costs and material waste in the packaging.

### SUMMARY

The present disclosure addresses the challenge of reducing costs and waste in the packaging of semiconductor devices. A temporary carrier provides a substrate upon which the semiconductor devices are assembled. After assembly, the completed semiconductor devices are removed from the carrier. The carrier is available for reuse in assembling additional semiconductor devices. Devices of various I/O counts may be produced by disclosed embodiments.

In an example embodiment, there is a method for assembling semiconductor devices. The method comprises, providing a temporary carrier having a plurality device die locations and a boundary edge. Electrical connection pads are applied surrounding the device die locations. Device die are mounted in the plurality of device die locations; the device die have pad landings which are electrically coupled to active components within the device die. The pad landings of the device are wire bonded to corresponding electrical connection pads. The device die is encapsulated in a molding compound, the molding compound flowing to the boundary edge of the temporary carrier. Additional features of the embodiment include, the removing of the temporary carrier, thereby exposing undersides of the electrical connection pads at the plurality of device locations. Further, the undersides of the electrical connection pads surrounded by molding compound may be planarized. The planarization provides a smooth, polished surface on the underside of the finished semiconductor device. After planarization, the devices are singulated.

In another example embodiment, there is a method for assembling semiconductor device and the method comprises providing a temporary carrier having a plurality device die locations and a boundary edge. At surrounding the device die locations electrical connection pads are applied. Device die are mounted in the plurality of device die locations; the device die have pad landings, the pad landings are electrically coupled to active components within the device die. The pad landings of the device die are wired bonded to corresponding electrical connection pads. The device die is encapsulated in a molding compound, the molding compound flowing to the boundary edge of the temporary carrier. The temporary carrier is removed, thereby exposing undersides of the electrical connections pads at the plurality of device locations. Undersides of the electrical connection pads and surrounding molding compound are planarized. Planarization continues until the electrical connection pads are flush with the surrounding molding compound. Device die are singulated into individual components.

In another example embodiment, there is a computer-controlled apparatus for preparing a temporary carrier for assembling semiconductor devices in an array. The apparatus comprises, a programmable controller having user-access to stored information for a given device die configuration. A handling mechanism manipulates the temporary carrier, wherein the temporary carrier includes a substrate having a working surface and an underside surface; fiducial marks are inscribed on the working surface of the substrate, wherein the fiducial marks delineate the array boundary thereon; attachment locations are on the underside surface, wherein the attachment locations facilitate handling of the temporary carrier by the handling mechanism. There is a pattern recognition device; the pattern recognition device scans the fiducial marks on the working surface of the substrate, whereupon finding fiducial marks, the pattern recognition device transmits coordinate information for the device die mounting locations and ball bond locations to the programmable controller, in response the programmable controller recalls the stored information for the given device die configuration, thereby generating targeting commands for ball bond placement. A ball bonder tool places ball bonds onto the working surface of the temporary carrier, the ball bonder and the handling mechanism responding to the generated targeting commands from the programmable controller. A further feature of the apparatus, includes a device die mounting tool, the device die mounting tool is provisioned to attach device die at the device die mounting locations corresponding to the ball bond locations in response to the generated targeting commands from the programmable controller.

The above summaries of the present disclosure are not intended to represent each disclosed embodiment, or every aspect, of the present invention. Other aspects and example embodiments are provided in the figures and the detailed description that follow.

### BRIEF DESCRIPTION OF THE DRAWINGS

The invention may be more completely understood in consideration of the following detailed description of various embodiments of the invention in connection with the accompanying drawings, in which:

FIGS. 1A-1B are a side-view and top view of the temporary carrier used for device assembly according to an embodiment of the present invention;

FIG. 2A-1 in an example embodiment, depicts a side-view electrical connection pads in the form of ball bonds placed on the temporary carrier of FIGS. 1A-1B, wherein the ball bonds are placed thereon prior to die attach;

FIG. 2A-2 in another example embodiment, depicts a side-view of electrical connection pads in the form of metal pads defined on the temporary carrier of FIGS. 1A-1B, wherein the metal pads are defined thereon prior to die attach;

FIG. 2B is a top-view depicting electrical connection pads on the temporary carrier of FIGS. 1A-1B wherein the electrical connection pads are placed thereon prior to die attach;

FIGS. 2C-2D are a side-view and top-view depicting the attached device(s) on the temporary carrier of FIGS. 1A-1B wherein the electrical connection pads in the form of ball bonds are placed thereon after die attach;

FIGS. 3A-3B are a side-view and top-view depicting the attached device surrounded by ball bonds on the temporary carrier depicted in FIGS. 1A-1B;

FIGS. 4A-4B are a side-view and top-view depicting the attached device(s) having been wire bonded to the ball bonds on the temporary carrier used in the assembly process according to an embodiment of the present disclosure;

FIGS. 5A-5B are a side-view and top-view depicting the device(s) of FIGS. 4A-4B encapsulated in a molding compound;

FIGS. 6A-6B is a side view and top-view depicting the encapsulated device(s) of FIGS. 5A-5B with the temporary carrier removed;

FIGS. 7A-7B is a side view and top view of the device(s) of FIGS. 6A-6B having been separated (i.e., “singulated”);

FIGS. 8A-8C shows a completed device in three views, emphasizing the exposed ball bonds; and

FIG. 9 is a view of a temporary carrier as used in the various embodiments of the present disclosure.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

The disclosed embodiments have been found useful in the assembly semiconductor devices on temporary carriers so as to reduce the cost of a completed device. For a given device die, a connection arrangement employing electrical connection pads is arranged about the die. The number of electrical connection pads is determined by the number of electrical connections the device die requires, the connections may be referred to as die pad landings. Within a defined region surrounded by the electrical connection pads, is a die attach area on which a device die is mounted. With wire bonds, the die pad landings are connected to the appropriate electrical connection pads. These ball bonds connect the semiconductor device to the outside world. After wire bonding, the device is encapsulated in a passivating envelope of molding compound. In production, there may be hundreds or thousands of device die arrayed on the temporary carrier, each device is electrically isolated in a molded matrix. Thus, each device may undergo electrical test and failing devices be culled out when the array is sawn; for convenience, the individual semiconductor devices are labeled before sawing. Separated devices (i.e., “singulated”) are prepared for shipping in lots as required by the end users.

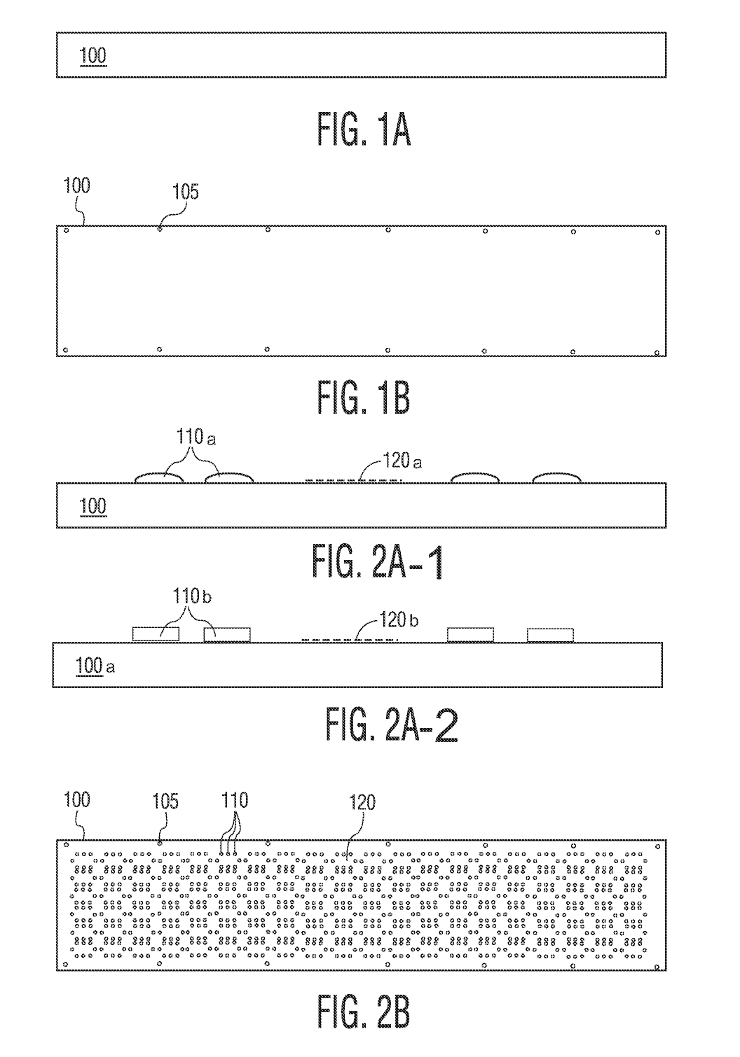

Refer to FIGS. 1A-1B. In an example embodiment, a carrier 100 is prepared for a given die configuration. The carrier 100 accommodates multiple semiconductor device dies and their electrical connection pads arrangement. Although, in the present embodiment, the carrier 100 is rectangular, the shape of the carrier is not limited. Depending upon the manufacturing apparatus used (such as a die/wire bonder), the shape of the temporary carrier may be modified to some other regular polygon or be circular so that a particular machine can accommodate it. Example bonding apparatus such as those manufactured by Kulicke & Soffa, ASM Pacific Technology Ltd. or others may be used.

The placement and arrangement of semiconductor device dies on the carrier 100 is programmed into the manufacturing apparatus, such apparatus being computer controlled. The program may consist of a mapping of a given device's die attach locations, the number of bonds needed to connect the device die's active regions to electrical connection pads, the number of device die placed on the temporary carrier, etc.

In an example embodiment, an apparatus for preparing a temporary carrier for assembling semiconductor devices in an array may be configured. The apparatus may comprise a programmable controller having user-access to stored information for a given device die configuration. Stored information may be retrieved from optical or magnetic media or from solid-state memory within the programmable controller. The user-access may be provided by a graphical user interface (GUI) alone or in combination with keyboard and mouse. In other configuration, there may be voice-controlled interfaces. Within the apparatus, a handling mechanism manipulates the temporary carrier as the electrical connection pads are defined thereon.

The temporary carrier may include a substrate having a working surface and an underside surface. Fiducial marks are inscribed on the working surface of the substrate. These fiducial marks delineate the array boundary thereon. Further there are attachment locations on the underside surface; the attachment locations facilitate handling of the temporary carrier by the handling mechanism. The apparatus has a pattern recognition device scanning the fiducial marks on the working surface of the substrate. Whereupon finding fiducial marks, the pattern recognition device transmits coordinate information for the device die mounting locations and ball bond locations to the programmable controller. In response the programmable controller recalls the stored information for the given device die configuration, thereby generating targeting commands for ball bond placement. A ball bonder tool (in the apparatus) places ball bonds onto the working surface of the temporary carrier; the ball bonder and the handling mechanism are responding to the generated targeting commands from the programmable controller.

Having placed the ball bonds, a device die mounting tool (in the apparatus) attaches device die at the device die mounting locations corresponding to the ball bond locations in response to the generated targeting commands from the programmable controller. In example embodiment, the temporary carrier is made of brass, although the carrier may be made of plastic, other metals, or printed circuit board material.

Reference holes 105 facilitate handling of the carrier during production. In addition, alignment patterns, such as fiducial marks (not illustrated) may be designed on the carrier as a reference to define the die pad and electrical connection pads location. Electrical connection pads 110 are defined on carrier 100 (FIGS. 2A-1 and 2A-2). A die attach area 120 is further defined on the carrier 100 and the electrical connection pads 110 surround the die attach area 120.

In one example embodiment, the electrical connection pads may consist of ball bonds 110a surrounding the die attach area 120a. Refer to FIG. 2A-1. These ball bonds 110a are applied to the temporary carrier 100 with a ball/wire bonder apparatus.

In an example embodiment, a semiconductor device die 50 having pad landings 60 defined thereon, may be secured by a die attach compound 55 to the die attach area 120 before the electrical connection pads 110, in particular the ball bonds 110a are defined. Refer to FIGS. 2C and 2D.

In another example embodiment, the electrical connection pads 110, the ball bonds 110a or metal features 110b may be placed on the temporary carrier 105 surrounding the die attach region 120a or 120b, respectively before die attaching the semiconductor device die 50. Refer to FIGS. 2B and 2D.

The number of electrical connection pads 110 is determined by the number of electrical connections the device die requires, the device die connections may be referred to as die pad landings. For the subsequent discussion, the electrical connection pads are ball bonds.

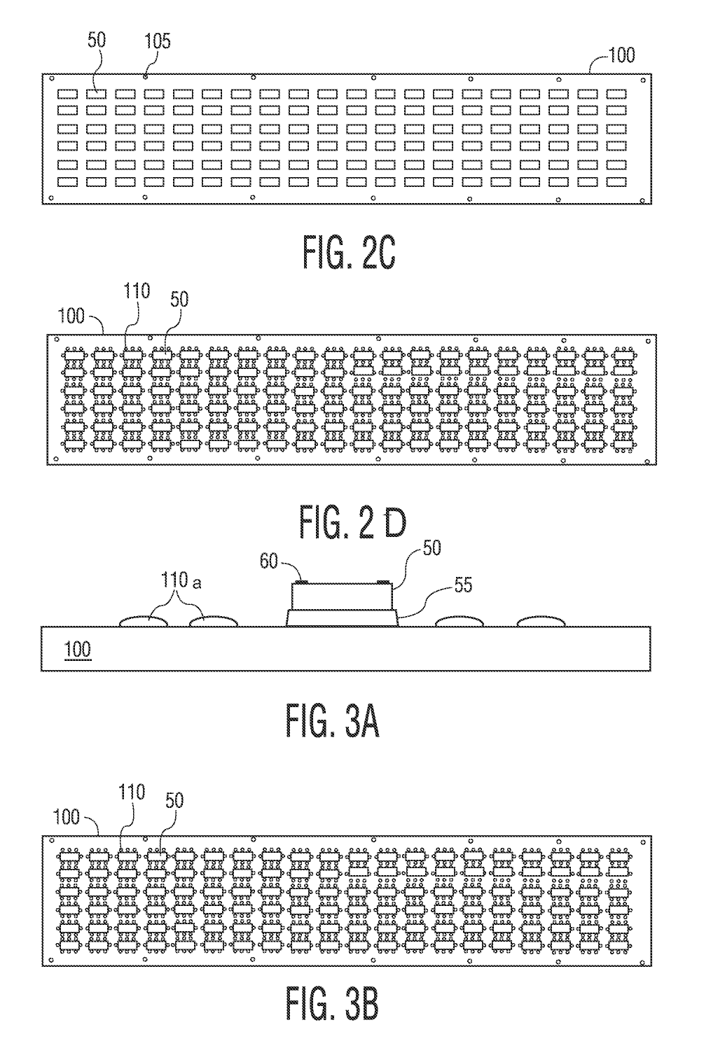

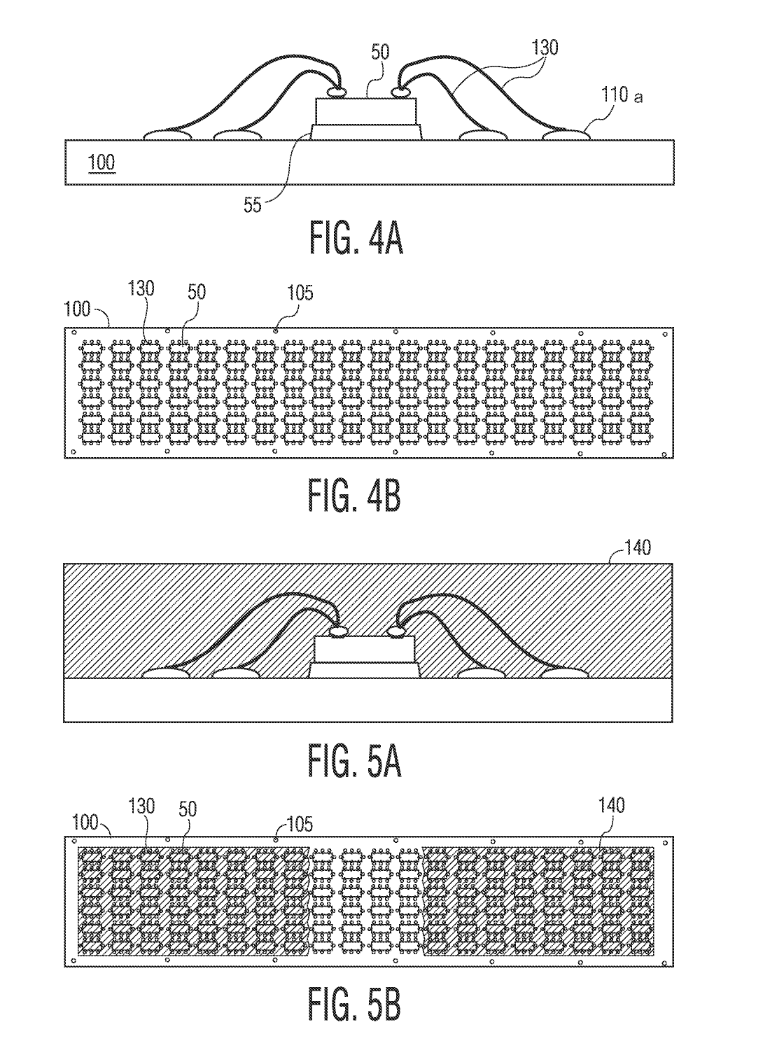

Referring to FIGS. 3A-3B, the after die attach, the semiconductor device die 50 has been attached (with a die attach material 55) and surrounded by ball bonds 110a. The device die 50 is wire bonded at the pad landings 60 to corresponding ball bonds 110a (FIGS. 4A-4B).

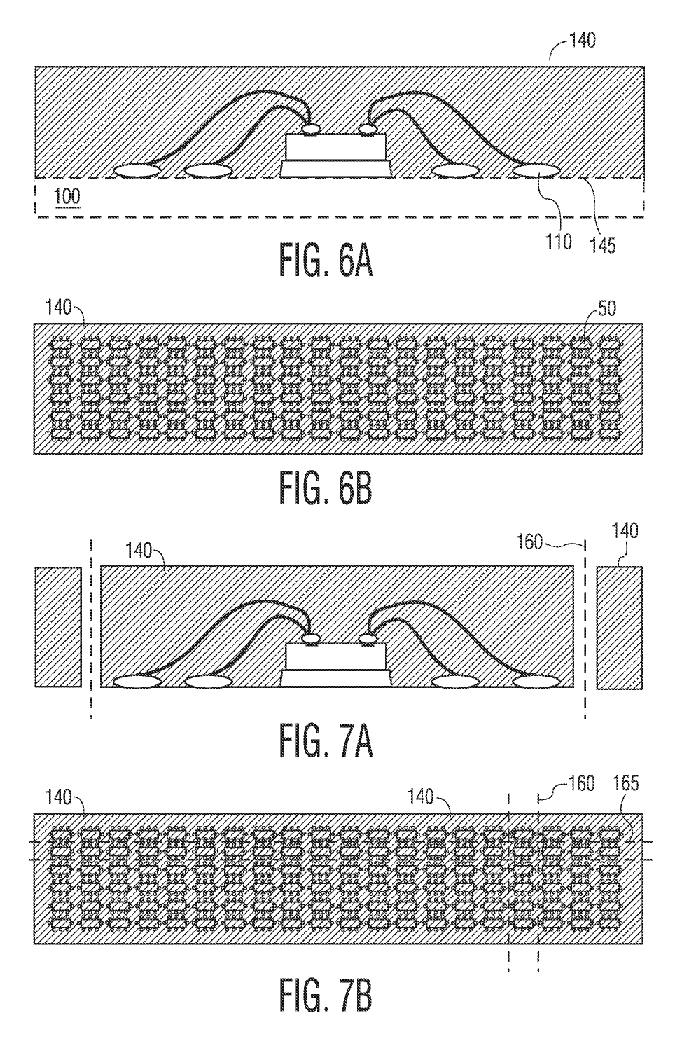

Wire bonds 130 connect the ball bonds 110a to the die pad landings 60, thus connecting the semiconductor device to the outside world. After wire bonding, the connected semiconductor device die 50 is encapsulated in a passivating envelope 140 (FIGS. 5A-5B). The passivating envelope 140 is a molding compound suitable for the given die configuration. For example, in one embodiment, the molding compound may be epoxy-based having a silicon filler so as to match the coefficient of temperature expansion (CTE) of the device die. FIG. 5B shows a cut-away of the molding compound 140. After the molding compound envelopes the carrier 100 and the array of multiple device dies 50, the carrier 100 is removed (See FIGS. 6A-6B). The lack of adhesion of the molding compound to the temporary carrier facilitates the carrier's removal. The ball bonds 110 are exposed on the underside 145 of the encapsulated device die. The array of multiple device dies are sawn apart in columns 160 and rows 165 in an operation referred to as “singulation.” In another example embodiment, an additional grinding, de-flashing or polishing step may be employed on the underside 145 of the encapsulated device die before singulation for better quality and yield.

The polishing serves to planarize the underside by polishing the ball bonds 110a so that they are flush with the surrounding molding compound. A planarization process may include chemical etching, chemical mechanical polishing. The resulting underside flatness facilitates soldering of the singulated components onto the user's printed circuit board.

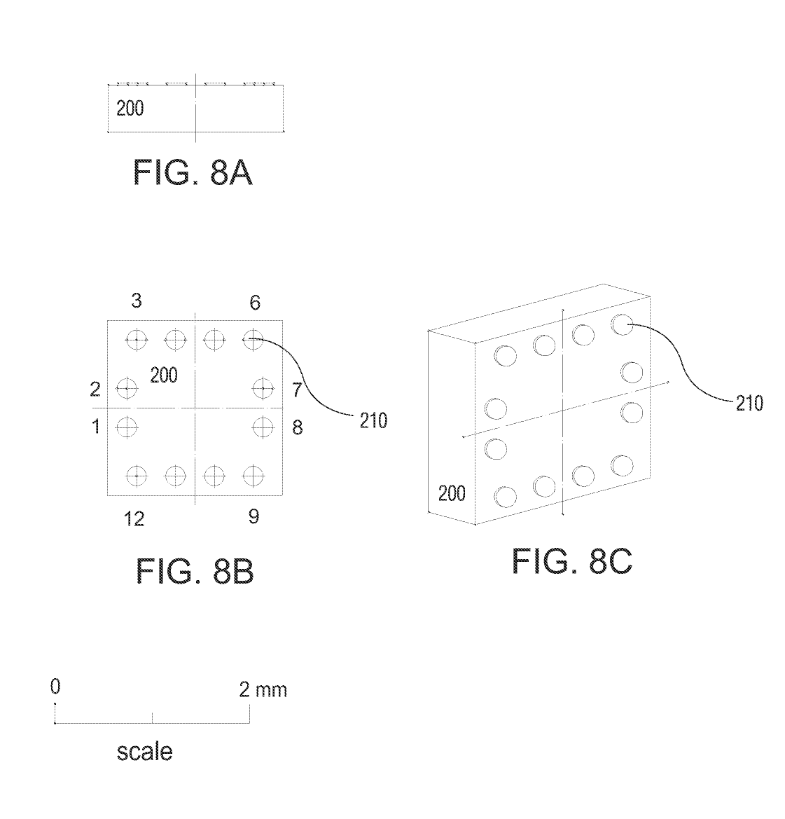

Refer to FIGS. 8A-8C. A packaged device 200 on its underside shows exposed ball bonds 210. FIG. 8B is a close-up view of the exposed ball bonds 210. FIG. 8C shows a perspective view of the packaged device. This example device has twelve connections via the exposed ball bonds 210.

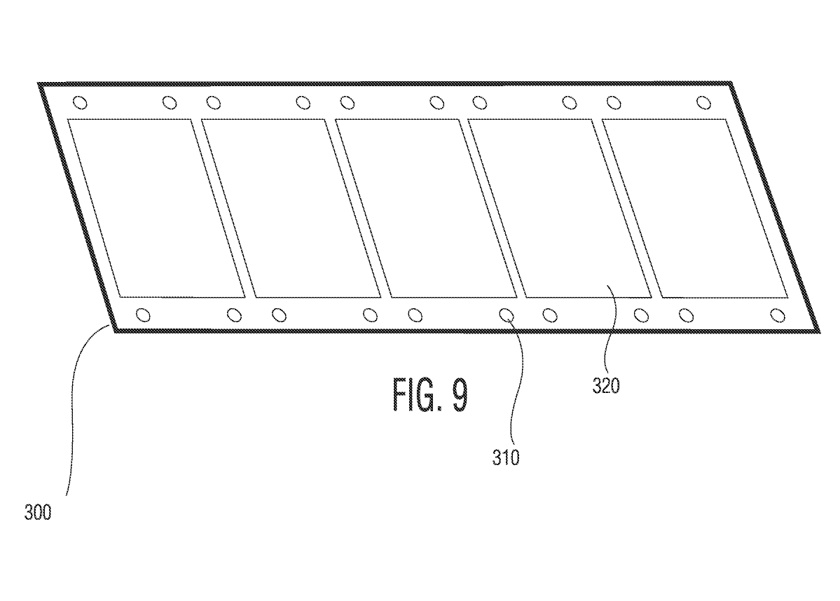

Refer to FIG. 9. A temporary carrier 300, carrier-material could be metal-base, or non-metal base. For example, the carrier material 300 may be polished brass. It may be a rectangular strip with fiducial marks 310, 320 (similar to the reference holes 105 of FIGS. 1A-1B) inscribed on or printed on for alignment purposes. Further, the fiducial marks 310, 320 provide reference as needed for die placement and ball bonds. After the molding process, the carrier strip will be separated from the molded matrix for reuse while the balls for external I/O contacts and dies remain with the molded matrix due to the relative lack of adhesion force to the temporary carrier. In an example embodiment according to the present disclosure, a quad-flat no-leads package (QFN) may be assembled. The number of device die depends on the silicon device's dimensions and selected carrier size. One example QFN may be 28 pins, another 3 or 4, or a hundred. A wire bonder defines the ball bonds (foot print) so that the pitch may be small than an example QFN or a multi-row QFN. In an example process a 30 μm pitch ball bond array may be achieved. The number of pins based on a minimum achievable pitch during a surface-mount-technology (SMT) process printed circuit board design (PCB), is about 0.5 mm and may be tighter at about 0.3 mm.

Numerous other embodiments of the invention will be apparent to persons skilled in the art without departing from the spirit and scope of the invention as defined in the appended claims.

1. A method for assembling semiconductor devices, the method comprising:
providing a temporary carrier having a plurality device die locations and a boundary edge;
applying electrical connection pads surrounding the device die locations;
mounting device die in the plurality of device die locations, the device die having pad landings, the pad landings electrically coupled to active components within the device die;
wire bonding the pad landings of the device die to corresponding electrical connection pads; and
encapsulating the device die in a molding compound, the molding compound flowing to the boundary edge of the temporary carrier.

2. The method as recited in claim 1, further comprising, removing the temporary carrier, thereby exposing undersides of the electrical connections pads at the plurality of device locations.

3. The method as recited in claim 2 wherein electrical connection pads are defined by ball bonds.

4. The method as recited in claim 2, further comprising planarizing the underside of the electrical connection pads and surrounding molding compound.

5. The method as recited in claim 4 wherein planarizing includes at least one of the following: chemical etching, chemical mechanical polishing.

6. The method as recited in claim 5, wherein the planarizing proceeds until the undersides of the electrical connection pads are flush with the surrounding molding compound.

7. The method as recited in claim 2, further comprising singulating the device die into individual components.

8. The method as recited in claim 3, further comprising singulating the device die into individual components.

9. A method for assembling semiconductor devices, the method comprising:
providing a temporary carrier having a plurality device die locations and a boundary edge;
applying electrical connection pads surrounding the device die locations;
mounting device die in the plurality of device die locations, the device die having pad landings, the pad landings electrically coupled to active components within the device die;
wire bonding the pad landings of the device die to corresponding electrical connection pads; and
encapsulating the device die in a molding compound, the molding compound flowing to the boundary edge of the temporary carrier;
removing the temporary carrier, thereby exposing undersides of the electrical connections pads at the plurality of device locations;
planarizing the undersides of the electrical connection pads and surrounding molding compound, wherein the planarizing continues until the electrical connection pads are flush with the surrounding molding compound; and
singulating the device die into individual components.

10. The method as recited in claim 9, wherein the electrical connection pads are defined by one of the following: ball bonds, metal mount features.

11. An apparatus for preparing a temporary carrier for assembling semiconductor devices in an array, the apparatus comprising:
a programmable controller having user-access to stored information for a given device die configuration;
a handling mechanism to manipulate the temporary carrier, wherein the temporary carrier includes,
a substrate having a working surface and an underside surface;
fiducial marks inscribed on the working surface of the substrate, wherein the fiducial marks delineate the array boundary thereon; and
attachment locations on the underside surface, wherein the attachment locations facilitate handling of the temporary carrier by the handling mechanism;
a pattern recognition device, the pattern recognition device scanning the fiducial marks on the working surface of the substrate, whereupon finding fiducial marks, the pattern recognition device transmits coordinate information for the device die mounting locations and ball bond locations to the programmable controller, in response the programmable controller recalls the stored information for the given device die configuration, thereby generating targeting commands for ball bond placement; and
a ball bonder tool which places ball bonds onto the working surface of the temporary carrier, the ball bonder and the handling mechanism responding to the generated targeting commands from the programmable controller.

12. The apparatus as recited in claim 11, further comprising, a device die mounting tool, the device die mounting tool provisioned to attach device die at the device die mounting locations corresponding to the ball bond locations in response to the generated targeting commands from the programmable controller.

13. The temporary carrier as recited in claim 12, wherein the substrate is made from at least one of the following materials: plastic, metal, printed circuit board (PCB).

14. The temporary carrier as recited in claim 13 wherein the substrate consists of brass.
